(19) United States
(12) Patent Application Publication
(10) Pub. No.: US 2022/0390509 A1
(43) Pub. Date: Dec. 8, 2022

(54) TESTING EQUIPMENT

(71) Applicant: SILICONWARE PRECISION INDUSTRIES CO., LTD., Taichung City (TW)

(72) Inventors: Li-Wei Lee, Taichung City (TW); Yung-Ming Wang, Taichung City (TW); Ping-Chieh Huang, Taichung City (TW); Tien-Yao Hsu, Taichung City (TW)

(73) Assignee: SILICONWARE PRECISION INDUSTRIES CO., LTD., Taichung City (TW)

(21) Appl. No.: 17/745,709

(22) Filed: May 16, 2022

(30) Foreign Application Priority Data
Jun. 2, 2021 (TW) 110120010

(51) Int. Cl. G01R 31/28

(52) U.S. Cl. CPC G01R 31/2896

(57) ABSTRACT

A testing equipment is provided, in which at least one testing module is disposed on a machine, and the testing module includes a circuit board, a testing carrier disposed on the circuit board and carrying a target object, and a processor disposed on the circuit board and electrically connected to the testing carrier, such that the testing module can operate and process a target information of the target object by itself via the processor, without connecting to an external computer to operate and process the target information of the target object, so as to quickly obtain a detecting information of the target object.

### BACKGROUND

### 1. Technical Field

The present disclosure relates to a testing equipment, and more particularly, to a testing equipment used for semiconductor packaging testing operations.

### 2. Description of Related Art

At present, wireless communication technology has been widely used in various consumer electronic products (such as mobile phones, tablet computers, etc.). In addition, with the development of high-speed computing, related semiconductor packages have gradually been used in autonomous driving, supercomputers or mobile devices and other industries.

At present, a semiconductor package needs to go through a burn-in process in the quality control stage before shipment. The burn-in process uses high temperature, high pressure or high humidity to perform reliability tests such as accelerated aging or destructiveness on the semiconductor packages that are expected to leave the factory, so as to detect the chips (ICs) in the poor semiconductor packages and eliminate them, so as to avoid subsequent recovery costs after leaving the factory.

As shown in FIG. 1, the conventional reliability detecting mechanism is that a plurality of semiconductor packages are disposed on a single testing socket 11, and a plurality of circuit boards 10 are arranged on a detecting area 1a of a testing equipment, each of the circuit boards 10 is respectively provided with the testing socket 11 (the testing socket can be connected with one or more packages), so that a computer 1 transmits detecting commands to each of the circuit boards 10, so that each of the testing sockets 11 captures the data required for various reliability tests of the semiconductor packages, and then, via a control chip 12 on each of the circuit boards 10, each of the testing sockets 11 is instructed to return the data required for various reliability tests of the semiconductor packages to the computer 1, so that the computer 1 can analyze and process the data.

However, in the conventional reliability detecting mechanism, if each of the semiconductor packages needs to perform a large number of test items and data collection of big data, the performance of the host of a single computer 1 is often unable to handle the required computational load, resulting in low detecting performance Therefore, the data processing speed of the computer 1 is extremely slow, and results in a very lengthy time course of the reliability detecting operation, thereby causing a delay in the shipping speed of the semiconductor package and its end products.

Furthermore, when the semiconductor package needs to perform a large number of test items and data collection of big data, the testing equipment needs to configure a plurality of transmission ports 100 on each of the circuit boards 10 to transmit these data to the computer 1, so the testing socket 11 needs to be customized to design a plurality of contacts electrically connected to the transmission ports 100. Therefore, the manufacturing cost of the testing socket 11 is increased, resulting in a substantial increase in the manufacturing cost of the detecting area 1a of the testing equipment, which is then transferred to the conventional reliability detecting operations, resulting in an increase in the cost of the conventional reliability detecting operations.

Furthermore, in the detecting area 1a, when the single circuit board 10 (or the testing socket 11 or the control chip 12 thereon) fails, the testing equipment needs to be shut down immediately, thereby affecting the time course of the overall testing operation, leading to an increase in the reliability detecting process, which in turn causes a delay in the shipment speed of the semiconductor package and its end products.

Therefore, how to overcome the above-mentioned drawbacks of the prior art has become an urgent issue to be solved at present.

### SUMMARY

In view of the various deficiencies of the prior art, the present disclosure provides a testing equipment, comprising: a machine; and at least one testing module disposed on the machine, wherein the testing module includes a circuit board, a testing carrier disposed on the circuit board and carrying a target object and a processor disposed on the circuit board and electrically connected to the testing carrier.

In the aforementioned testing equipment, a plurality of the testing modules are disposed on the machine.

In the aforementioned testing equipment, the machine is electrically connected to the circuit board.

In the aforementioned testing equipment, the circuit board is electrically connected to the testing carrier and/or the processor.

In the aforementioned testing equipment, the testing carrier is used for capturing a target information of the target object. For example, the processor is used for processing the target information of the target object to calculate a detecting information of the target object. Further, the testing module exports the detecting information for compiling operations.

In the aforementioned testing equipment, the testing equipment further comprises a controller disposed on the circuit board. For example, the controller is electrically connected to the circuit board. Alternatively, the controller is electrically connected to the testing carrier and/or the processor.

In the aforementioned testing equipment, the circuit board has at least one transmission port electrically connected to the testing carrier.

As can be seen from the above, the testing equipment of the present disclosure mainly employs a design of the processor configured on the circuit board, so that the testing module can calculate and process the target information of the target object by itself, so as to quickly obtain the detecting information of the target object. Therefore, compared with the prior art, when each of the target objects needs to perform a large number of test items and data collection of big data, the testing module can calculate and process the required data by itself via the processor it cooperates with. And the host of the computer only needs to receive the detecting information for compiling, so the load of the computer for processing data can be reduced, such that the data processing speed of the computer will be greatly increased, so that the time course of the reliability detecting operation will be greatly shortened, so that the target object and its end products can be shipped on time.

Furthermore, because the processor is configured on the testing module, when the target object needs to perform a large number of test items and data collection of big data, the testing equipment only needs to configure a small number of transmission ports on the circuit board to transmit the detecting information to the computer, so the testing carrier only needs to be modularly designed to electrically connect the contacts of the transmission ports without customizing the testing carrier. Therefore, the testing equipment of the present disclosure can reduce the manufacturing cost of the testing carrier, so that the manufacturing cost of the testing equipment can be greatly reduced, so as to reduce the cost of reliability detecting operations.

### BRIEF DESCRIPTION OF THE DRAWINGS

FIG. 1 is a schematic configuration view of a conventional reliability detecting mechanism.

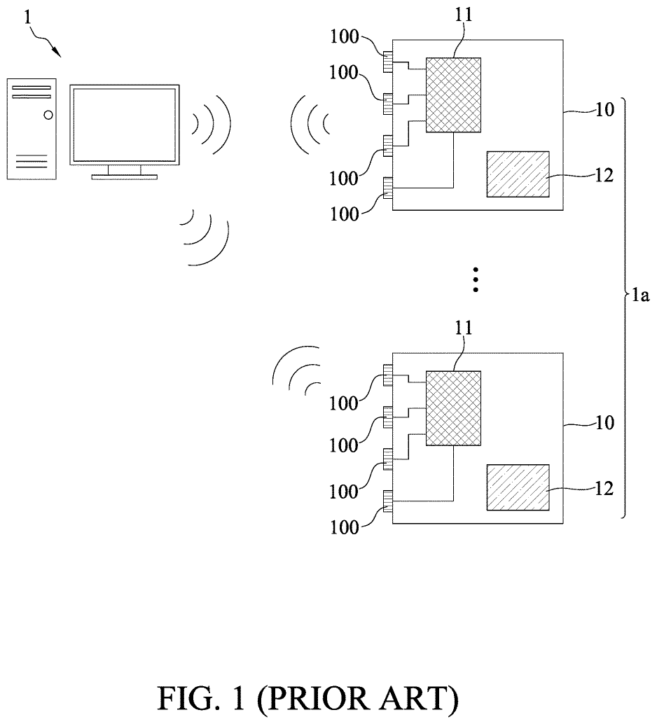

FIG. 2 is a schematic structural view of a testing equipment according to the present disclosure.

FIG. 3 is a schematic configuration view of the testing equipment when in use according to the present disclosure.

### DETAILED DESCRIPTIONS

The following describes the implementation of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “upper,” “one” and the like used herein are merely used for clear explanation rather than limiting the practicable scope of the present disclosure, and thus, alterations or adjustments of the relative relationships thereof without essentially altering the technical contents should still be considered in the practicable scope of the present disclosure.

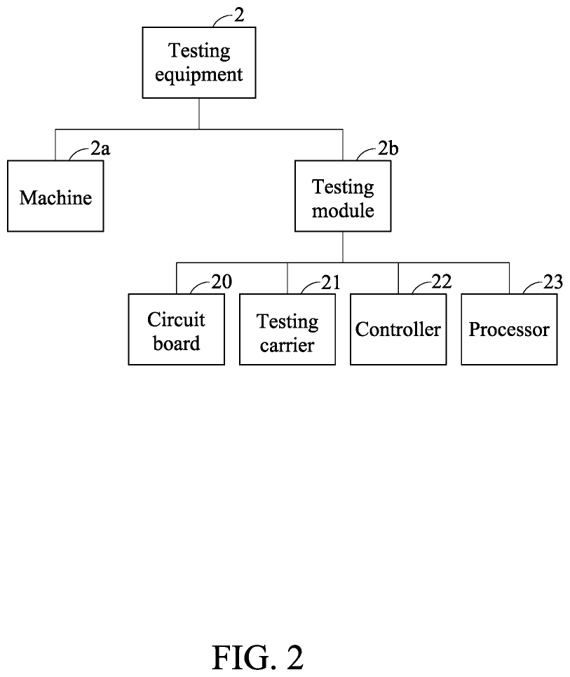

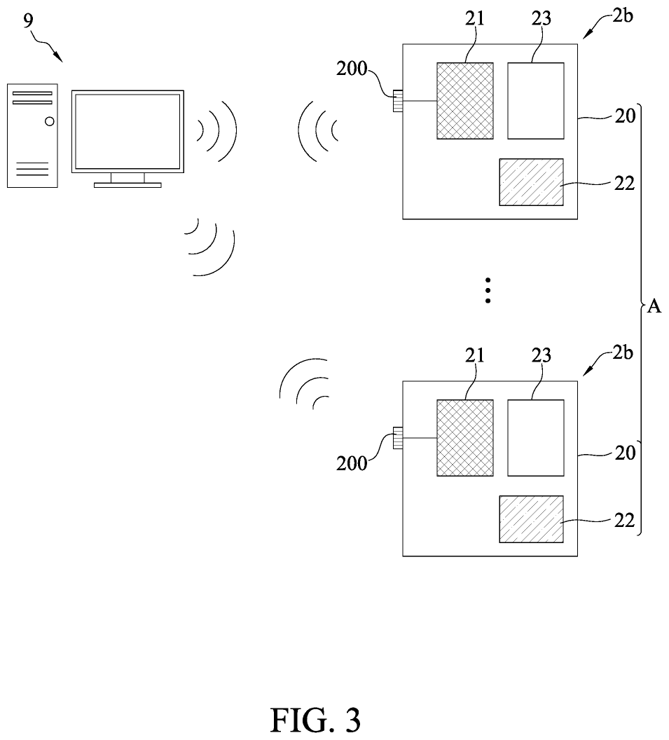

FIG. 2 and FIG. 3 are a schematic structural view of a testing equipment 2 according to the present disclosure and a schematic configuration view of the testing equipment 2 when in use according to the present disclosure. In an embodiment, the testing equipment 2 is used for reliability testing of a target object (not shown).

The target object is an electronic package, which includes at least one semiconductor chip and a cladding body covering the semiconductor chip, and the material for forming the cladding body is an insulating material such as polyimide (PI), dry film, epoxy resin, or molding compound, but not limited to the above.

The testing equipment 2 includes: a machine 2a having a detecting area A, and at least one testing module 2b arranged on the detecting area A. In an embodiment, a plurality of the testing modules 2b are arranged on the detecting area A of the machine 2a.

The testing module 2b includes a circuit board 20, a testing carrier 21 disposed on the circuit board 20 and carrying the target object, and a processor 23 disposed on the circuit board 20 and electrically connected to the testing carrier 21.

The machine 2a is electrically connected to the circuit board 20. In an embodiment, the machine 2a can be configured with a design of related electromechanical integration according to the requirements of the test items, and there is no particular limitation.

The circuit board 20 is electrically connected to the testing carrier 21 and/or the processor 23. In an embodiment, the circuit board 20 has a transmission port 200 electrically connected to the testing carrier 21, in the form of a contact as shown in FIG. 3.

The testing carrier 21 is in the form of a testing socket, which carries a plurality of target objects to capture the target information of the target objects.

In an embodiment, the testing carrier 21 is communicatively connected to a computer 9 to receive an instruction from the computer 9, and then capture the target information of the target objects.

Furthermore, the target information is determined according to the relevant data required by the test item, for example, the electrical specifications of the electronic package required for a reliability test, the materials used, or the like.

The processor 23 receives the target information of the testing carrier 21 via the circuit board 20 to process the target information to calculate the detecting information of the target objects.

In an embodiment, the processor 23 performs calculations on the test items, so the detecting information is the detecting result. For example, the processor 23 uses the target information to perform the reliability test, so as to calculate the aging data or destructive data of the electronic package under specified conditions (such as the temperature, pressure, or other environmental settings set by the machine 2a), for use as the detecting information.

Furthermore, the testing module 2b exports the detecting information for compiling operations. For example, the detecting information can be transmitted to a computer 9, so that the computer 9 can compile multiple sets of the detecting information.

The testing module 2b further includes a controller 22 disposed on the circuit board 20, and the controller 22 is electrically connected to the circuit board 20.

In an embodiment, the controller 22 includes at least one control chip, which is electrically connected to the testing carrier 21 and/or the processor 23 to control the operations of the testing carrier 21 and/or the processor 23.

When using the testing equipment 2, a computer 9 is communicatively connected (such as wireless or by a transmission line) to the testing equipment 2, as shown in FIG. 3, so that the user sends an instruction to the controller 22 via the computer 9, such that the controller 22 operates the testing carrier 21 to obtain the required target information, and then the controller 22 operates the processor 23 to transmit the detecting information to the computer 9 via the transmission port 200 after the single processor 23 calculates the detecting information of the plurality of target objects on the testing carrier 21. The computer 9 is made to store the detecting information, and even organize or count multiple detecting information from the plurality of the testing modules 2b.

Therefore, the testing equipment 2 of the present disclosure is mainly configured with a processor 23 carrying a plurality of target objects on the testing module 2b, so that the testing module 2b can automatically calculate and process the object information of the target objects to quickly obtain the detecting information of the target objects. Therefore, compared with the prior art, when each of the target objects needs to perform a large number of test items and data collection of big data, the testing module 2b can calculate and process the required data by itself via the processor 23 it cooperates with. And the host of the computer 9 only needs to receive the detecting information (such as the detecting result) for compiling, so the operation performance of the computer 9 is bound to be able to handle the required processing amount.

To sum up, since the testing equipment 2 can quickly process data with high computational load, so as to greatly improve the detecting performance and reduce the load of the computer 9 for processing data, the data processing speed of the computer 9 will be greatly increased, so that the time course of the reliability detecting operation will be greatly shortened, so that the target object and its end products can be shipped on time.

Furthermore, because the processor 23 is configured on the testing module 2b, when the target object needs to perform a large number of test items and data collection of big data, the testing equipment 2 only needs to configure a small number (such as one) of transmission ports 200 on the circuit board 20 to transmit the detecting information (such as the detecting result) to the computer 9, so the testing carrier 21 only needs to be modularly designed to electrically connect the contacts of the transmission ports 200 without customizing the testing carrier 21. Therefore, the testing equipment 2 of the present disclosure can reduce the manufacturing cost of the testing carrier 21, so that the manufacturing cost of the detecting area A of the testing equipment 2 can be greatly reduced, so as to reduce the cost of reliability detecting operations.

In addition, when a single testing module 2b fails, the other testing modules 2b can still operate continuously, so that the machine 2a does not need to be shut down. Therefore, compared with the prior art, the testing module 2b of the present disclosure still operates independently, so it will not affect the time course of the overall testing operation, so that the target object and its end products can be shipped on time.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. A testing equipment, comprising:
a machine; and
at least one testing module disposed on the machine, wherein the testing module includes a circuit board, a testing carrier disposed on the circuit board and carrying a target object and a processor disposed on the circuit board and electrically connected to the testing carrier.

2. The testing equipment of claim 1, wherein a plurality of the testing modules are disposed on the machine.

3. The testing equipment of claim 1, wherein the machine is electrically connected to the circuit board.

4. The testing equipment of claim 1, wherein the circuit board is electrically connected to the testing carrier and/or the processor.

5. The testing equipment of claim 1, wherein the testing carrier is used for capturing a target information of the target object.

6. The testing equipment of claim 5, wherein the processor is used for processing the target information of the target object to calculate a detecting information of the target object.

7. The testing equipment of claim 6, wherein the testing module exports the detecting information for compiling operations.

8. The testing equipment of claim 1, further comprising a controller disposed on the circuit board.

9. The testing equipment of claim 8, wherein the controller is electrically connected to the circuit board.

10. The testing equipment of claim 8, wherein the controller is electrically connected to the testing carrier and/or the processor.

11. The testing equipment of claim 1, wherein the circuit board has at least one transmission port electrically connected to the testing carrier.
